(19) United States
(12) Patent Application Publication
(10) Pub. No.: US 2008/0246144 A1
(43) Pub. Date: Oct. 9, 2008

(54) METHOD FOR FABRICATING CONTACT PADS

(76) Inventors: Ping-Chang Wu, Hsin-Chu Hsien (TW); Chieh-Ching Huang, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 11/695,617

(22) Filed: Apr. 3, 2007

(51) Int. Cl. H01L 23/48; H01L 21/4763

(52) U.S. Cl. 257/737; 438/614; 257/E23.01; 257/E21.495

(57) ABSTRACT

A method for fabricating a contact pad is disclosed. A first metal layer is disposed on a substrate for serving as a probing region. A second metal layer is disposed on the substrate thereafter to serve as an electrical connection region. Preferably, the first metal layer and the second metal layer are composed of different material and are electrically connected. The present invention uses two different metals to form a probing region and an electrical connection region of a contact pad. The probing region is used for providing a contacting surface for a test probe, whereas the electrical connection region is used for establishing an electrical connection in the later bumping or wire bonding process. By providing a contact pad having two different regions, the present invention is able to achieve probing process while prevent the surface of the contact pad from being damaged by the contact of test probes.

### BACKGROUND OF THE INVENTION

1. Field of the Invention

The invention relates to a method for fabricating a contact pad.

2. Description of the Prior Art

In creating semiconductor devices, the technology of interconnecting devices and device features is a continuing challenge in the era of sub-micron devices. Contact pads are frequently used for this purpose, in which numerous efforts have been dedicated to provide contact pads that are reliable, simple, and effective.

Contact pads, having dimensions of between about 40×40 μm and 120×120 μm, are in current practice frequently used as access or input/output contact points during wafer level testing of semiconductor devices. During the entire phase of testing, these contact pads be contacted a number of times. Testing is typically performed at high speed, which frequently results in landing the test probe on the surface of the contact pad at high speed, resulting in mechanical damage to the surface of the contact pad. Testing is especially important for memory products. In order to increase the yield for memory products, a plurality of redundant cells is often prepared for repairing purpose. During the initial phase of memory testing, test probes are used to examine the quality of redundant cells. The cells that are of lower grade will be repaired by a laser repairing process, such that the repaired units will be prepared for more testing thereafter. Hence for memory products, a wafer is tested at least two times.

As described previously, during the phase of probe testing, the surface of the contact pad will be damaged frequently. Surface damage to the contact pad may occur in the form of a dent (in the surface of the contact pad) or may even become severe enough that the surface of the contact pad is disrupted, resulting in the occurrence of burring in the surface of the contact pad. After the probing process is completed, a portion of the contact pads will be used for bumping process or wire bonding processes, in which a plurality of bumps or wires will be formed on top of the contact pads for electrically connecting to other devices.

Please refer to FIGS. 1-4. FIGS. 1-4 illustrate a method for fabricating a contact pad according to the prior art. As shown in FIG. 1, a substrate having at least one metal interconnects (not shown) and a dielectric layer 12 thereon is provided, in which the substrate is a wafer or a silicon on insulator substrate. A pattern transfer process is performed by using a patterned mask to form an opening (not shown) in the dielectric layer 12. A first metal layer 14 is then disposed on the dielectric layer 12 and a chemical mechanical polishing process is performed to form a damascene conductor in the dielectric layer 12. The first metal layer 14 is preferably composed of copper.

As shown in FIG. 2, a dielectric layer 16 is disposed on the first metal layer 14 and the dielectric layer 12, and another pattern transfer process is performed to form an opening 18 in the dielectric layer 16. Next, as shown in FIG. 3, a second metal layer 20 is disposed on the dielectric layer 16 and into the opening 18. The second metal layer 16 can be composed of copper or aluminum. As shown in FIG. 4, an etching process is performed by using a patterned mask (not shown) to remove a portion of the second metal layer 20 for exposing the dielectric layer 16, thus complete the fabrication of a contact pad 22.

A probing process can be conducted thereafter by using a test probe to examine the completeness of the internal circuits to ensure that the contact pad is capable of achieving proper electrical connection in the later process. After the probing process is completed, a wire bonding or a bumping process is performed on the contact pad. However, since the conventional contact pad is composed of only one metal, the surface of the contact is often disrupted from the contact of test probe during the probing process, thus resulting in unreliable bumps or wires.

### SUMMARY OF THE INVENTION

It is an objective of the present invention to provide a contact pad for solving the aforementioned problems.

A method for fabricating a contact pad is disclosed. The method includes: providing a substrate having at least one metal interconnects; forming a first metal layer on the substrate for serving as a probing region; and forming a second metal layer on the substrate for serving as an electrical connection region, in which the first metal layer and the second metal layer are comprised of different material and are electrically connected.

A contact pad is disclosed, in which the contact pad includes a substrate having at least one metal interconnects; a first metal layer disposed on the substrate for serving as a probing region; and a second metal layer disposed on the substrate for serving as an electrical connection region, in which the first metal layer and the second metal layer are comprised of different material and are electrically connected.

According to another aspect of the present invention, a method for fabricating a contact pad is disclosed. The method includes: providing a substrate having at least one metal interconnects and a first metal layer thereon; forming a dielectric layer on the substrate and the first metal layer; forming an opening in the dielectric layer for exposing a portion of the first metal layer; forming a second metal layer on the dielectric layer and in the opening for forming a metal plug electrically connecting the first metal layer and the second metal layer, wherein the first metal layer and the second metal layer comprise different materials; removing a portion of the second metal layer; forming a passivation layer on the second metal layer and a portion of the dielectric layer; and removing a portion of the passivation layer for exposing a portion of the first metal layer and the second metal layer, wherein the exposed portion of the first metal layer is a probing region and the exposed portion of the second metal layer is an electrical connection region.

According to another aspect of the present invention, a contact pad is disclosed. The contact pad includes a substrate having at least one metal interconnects; a first metal layer disposed on the substrate, wherein the surface of the first metal layer is exposed for serving as a probing region; a second metal layer disposed on the substrate for serving as an electrical connection region, wherein the first metal layer and the second metal layer comprise different materials; and a metal plug, disposed between the first metal layer and the second metal layer for electrically connecting the first metal layer and the second metal layer.

The present invention uses two different metals to form a probing region and an electrical connection region of a contact pad. The probing region is used for providing a contacting surface for a test probe, whereas the electrical connection region is used for establishing an electrical connection in the later bumping or wire bonding process. By providing a contact pad having two different regions, the present invention is able to achieve probing process while prevent the surface of the contact pad from being damaged by the contact of the test probe.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating a contact pad according to the prior art.

FIGS. 5-9 illustrate a method for fabricating a contact pad according to the preferred embodiment of the present invention.

FIGS. 10-13 illustrate a top view of defining an electrical connection region and a probing region on a contact pad according to the present invention.

FIGS. 14-18 illustrate a method for fabricating a contact pad according to an embodiment of the present invention.

FIGS. 19-25 illustrate a method for fabricating a contact pad according to an embodiment of the present invention.

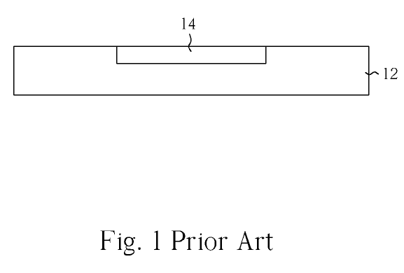

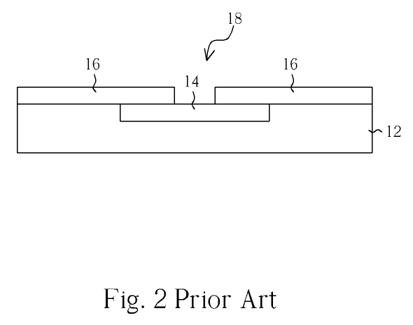

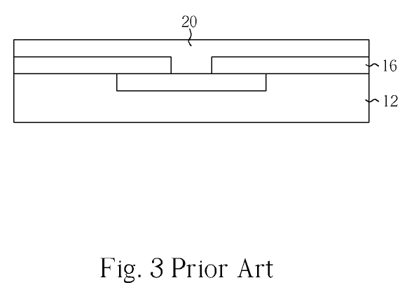

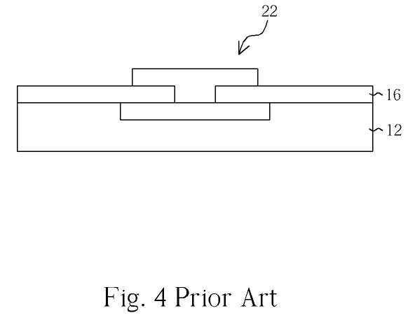

### DETAILED DESCRIPTION

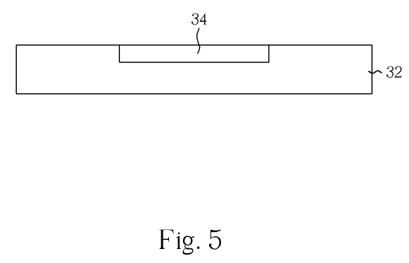

Please refer to FIGS. 5-9. FIGS. 5-9 illustrate a method for fabricating a contact pad according to the preferred embodiment of the present invention. As shown in FIG. 5, a substrate having at least one metal interconnects (not shown) and a dielectric layer 32 thereon is provided, in which the substrate is a wafer or a silicon on insulator substrate. Next, a pattern transfer process is performed by using a patterned mask (not shown) to conduct an etching process for forming an opening (not shown) in the dielectric layer 32. Thereafter, a first metal layer 34 is disposed on the dielectric layer 32 and into the opening and a planarizing process, such as a chemical mechanical polishing process is performed to form a damascene conductor in the dielectric layer 32. The first metal layer 34 is preferably composed of copper.

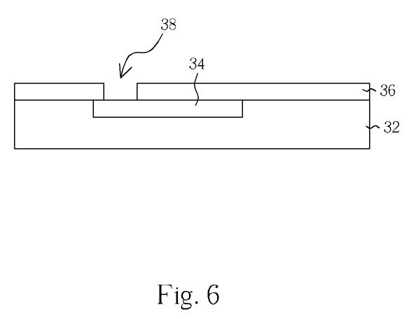

As shown in FIG. 6, a first dielectric layer 36 is formed on the first metal layer 34 and the dielectric layer 32, and another pattern transfer process is performed by using a patterned mask (not shown) to perform an etching process for forming an opening 38 in the first dielectric layer 36 and exposing the first metal layer 34 from the opening 38.

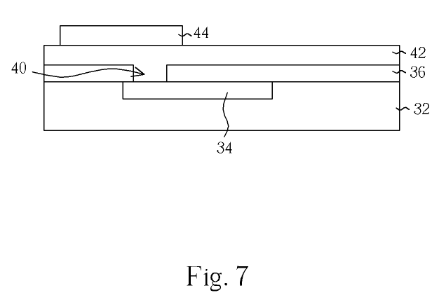

Next, as shown in FIG. 7, a second metal layer 42 is deposited on the first dielectric layer 36 and into the opening 38, in which the portion of the second metal layer 42 filled into the opening 38 forms a metal plug 40 for electrically connecting the second metal layer 42 and the first metal layer 34. Preferably, the second metal layer 42 and the first metal layer 34 are composed of different material, in which the second metal layer 42 in this embodiment is composed of aluminum. However, not limited by the fabrication order described above, the present invention can also form a first metal layer 34 composed of aluminum in the dielectric layer 32, and form a second metal layer 42 composed of copper on the first dielectric layer 36 thereafter and connecting the first metal layer 34 and the second metal layer 42, which are all within the scope of the present invention.

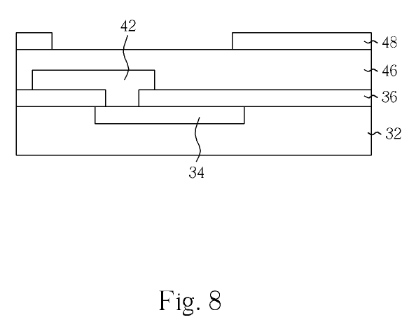

Thereafter, a patterned mask, such as a patterned second dielectric layer 44 is formed on the second metal layer 42, and an etching process is performed by using the patterned second dielectric layer 44 as a mask to remove a portion of the second metal layer 42. As shown in FIG. 8, a passivation layer 46 is formed on the second metal layer 42 and the first dielectric layer 36, and another patterned mask, such as a patterned third dielectric layer 48 is used to perform another etching process for removing a portion of the passivation layer 46 and the first dielectric layer 36 and exposing a portion of the first metal layer 34 and the second metal layer 42. The exposed first metal layer 34 and the second metal layer 42 can be used as an electrical connection region or a probing region in the later process. The electrical connection region is preferably used for either bumping process or wire bonding process.

According to the preferred embodiment of the present invention, the first metal layer 34 composed of copper is used as an electrical connection region for later bumping process, whereas the second metal layer 42 composed of aluminum is used as a probing region for electrical testing. Nevertheless, if the first metal layer 34 composed of copper is used as a probing region for electrical testing, the second metal layer 42 composed of aluminum can be used as an electrical connection region for wire bonding processes.

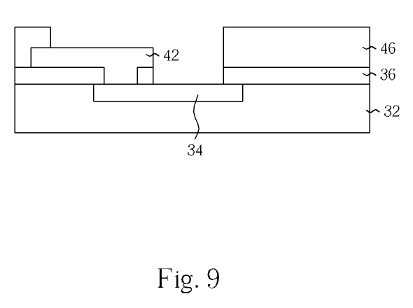

Additionally, the patterned third dielectric layer 48 can be used as a mask to completely remove the passivation layer 46 covering the first metal layer 34 and the second metal layer 42, as shown in FIG. 9, or remove only a portion of the passivation layer 46 for defining the electrical connection region and the probing region of the contact pad.

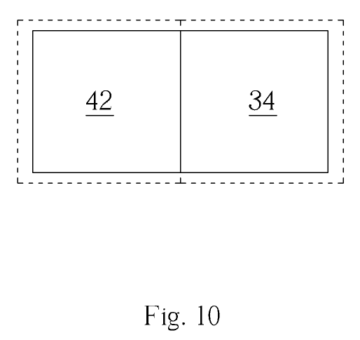

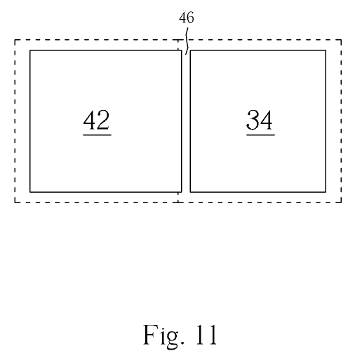

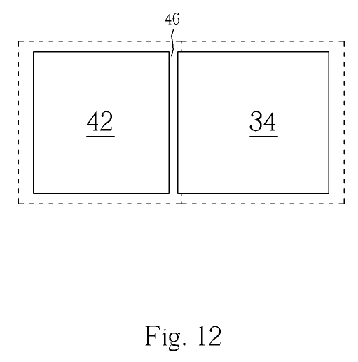

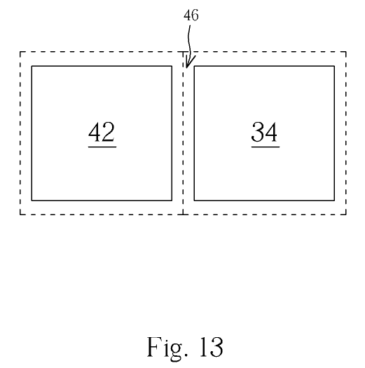

Please refer to FIGS. 10-13. FIGS. 10-13 illustrate a top view of defining an electrical connection region and a probing region on a contact pad according to the present invention. For instance, an etching process is conducted by using the patterned third dielectric layer 48 as a mask to completely remove the passivation layer 46 covering the first metal layer 34 and the second metal layer 42, as shown in FIG. 10. Alternatively, instead of removing the passivation layer 46 completely, the pattern of the third dielectric layer 48 can be adjusted to remove only a portion of the passivation layer 46, such as leaving a portion of the passivation layer 46 on the first metal layer 34, as shown in FIG. 11, or leaving a portion of the passivation layer 46 on the second metal layer 42, as shown in FIG. 12, or leaving a portion of the passivation layer 46 on both the first metal layer 34 and the second metal layer 42, as shown in FIG. 13. In other words, the location and area of the passivation layer 46 covering the first metal layer 34 and the second metal layer 42 can be adjusted according to the demand of various products for defining the electrical connection region and probing region of the contact pad.

It should be noted that the present invention principally uses two different metals to form a probing region and an electrical connection region of a contact pad. The probing region is used for providing a contacting surface for a test probe, whereas the electrical connection region is used for establishing an electrical connection in the later bumping or wire bonding process. By providing a contact pad having two different regions, the present invention is able to achieve probing process while prevent the surface of the contact pad from being damaged by the contact of a test probe.

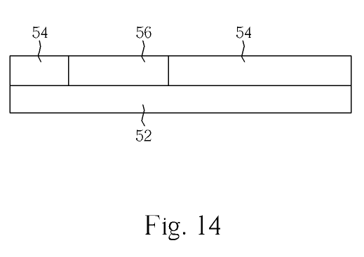

Please refer to FIGS. 14-18. FIGS. 14-18 illustrate a method for fabricating a contact pad according to an embodiment of the present invention. As shown in FIG. 14, a substrate having at least one metal interconnects and a dielectric layer 52 thereon is provided, in which the substrate is a wafer or a silicon on insulator substrate. After another dielectric layer 54 is disposed on the dielectric layer 52, a pattern transfer process is performed by using a patterned mask (not shown) to conduct an etching process for forming a plurality of openings (not shown) in the dielectric layer 54. Thereafter, a first metal layer 56 is disposed on the dielectric layer 54 and into the openings and a planarizing process, such as a chemical mechanical polishing process is performed to remove the first metal layer 56 disposed on the dielectric layer 54, such that the surface of the first metal layer 56 is even with the surface of the dielectric layer 54. The first metal layer 56 is preferably composed of copper.

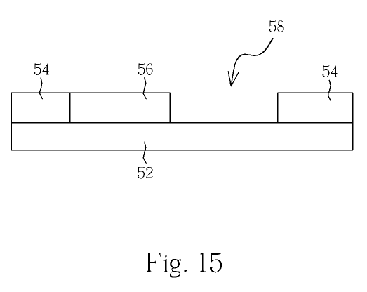

As shown in FIG. 15, an etching process is performed by using another patterned mask (not shown) to remove a portion of the dielectric layer 54 adjacent to the first metal layer 56 for forming an opening 58.

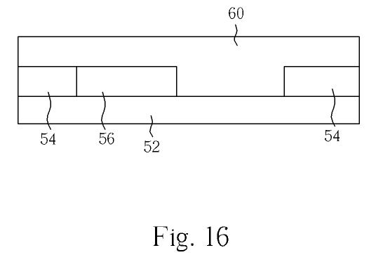

As shown in FIG. 16, a second metal layer 60 is deposited on the first metal layer 56, the dielectric layer 54 and into the opening 58. The second metal layer 60 is composed of a material different from the first metal layer 56, such as in this embodiment, the second metal layer 60 is composed of aluminum. However, not limited by the fabrication order described above, the present invention can also dispose a first metal layer 56 composed of aluminum on the dielectric layer 52, and form a second metal layer 60 composed of copper adjacent to the first metal layer 56 thereafter and connecting the first metal layer 56 and the second metal layer 60, which are all within the scope of the present invention.

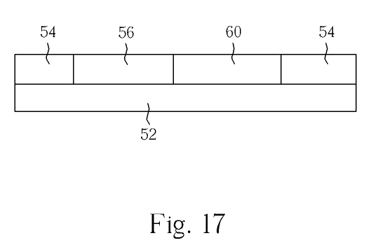

As shown in FIG. 17, another chemical mechanical polishing process is performed to remove the second metal layer 60 disposed on the first metal layer 56 and the dielectric layer 54, such that the surface of the second metal layer 60 is even with the surface of the dielectric layer 60 and the first metal layer 56.

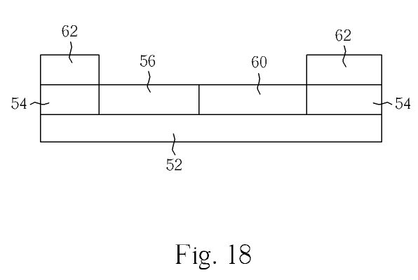

As shown in FIG. 18, a patterned passivation layer 62 is disposed on the dielectric layer 54 and a portion of the first metal layer 56 and the second metal layer 60 for defining a probing region for electrical testing and an electrical connection region for bumping or wire bonding processes. As described in aforementioned FIGS. 10-13, the location of the passivation layer 62 disposed on the first metal layer 56 and the second metal layer 60 can be adjusted accordingly. For instance, the passivation layer 62 can be disposed only on a portion of the first metal layer 56, only on a portion of the second metal layer 60, or on both the first metal layer 56 and the second metal layer 60.

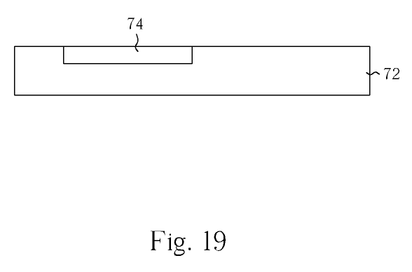

Please refer to FIGS. 19-25. FIGS. 19-25 illustrate a method for fabricating a contact pad according to an embodiment of the present invention. As shown in FIG. 19, a substrate having at least one metal interconnects and a dielectric layer 72 thereon is provided, in which the substrate is a wafer or a silicon on insulator substrate. Next, a pattern transfer process is performed by using a patterned mask (not shown) to conduct an etching process for forming an opening (not shown) in the dielectric layer 72. Thereafter, a first metal layer 74 is disposed on the dielectric layer 72 and into the opening and a planarizing process, such as a chemical mechanical polishing process is performed to form a damascene conductor in the dielectric layer 72. The first metal layer 74 is preferably composed of copper.

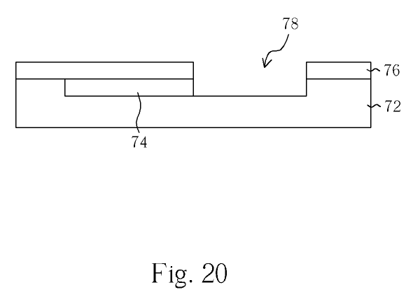

As shown in FIG. 20, a first dielectric layer 76 is formed on the first metal layer 74 and the dielectric layer 72, and another pattern transfer process is performed by using a patterned mask (not shown) to perform an etching process for forming an opening 78 in the first dielectric layer 76 and the dielectric layer 72 adjacent to the first metal layer 74.

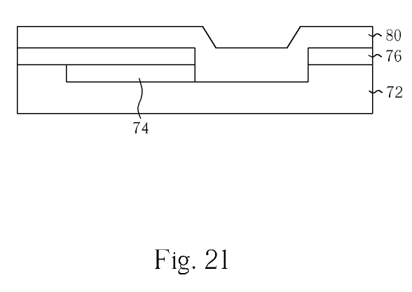

As shown in FIG. 21, a second metal layer 80 is deposited on the first dielectric layer 76 and into the opening 78, in which the second metal layer 80 disposed in the opening 78 is electrically connected to the adjacent first metal layer 74. Preferably, the first metal layer 74 and the second metal layer 80 are composed of different material, in which the second metal layer 80 in this embodiment is composed of aluminum. However, not limited by the fabrication order described above, the present invention can also form a first metal layer 74 composed of aluminum in the dielectric layer 72, and dispose a second metal layer 80 composed of copper on the dielectric layer 72 thereafter and connecting the first metal layer 74 and the second metal layer 80, which are all within the scope of the present invention.

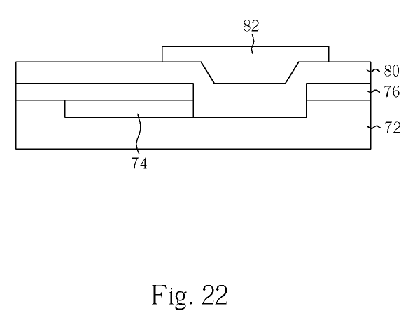

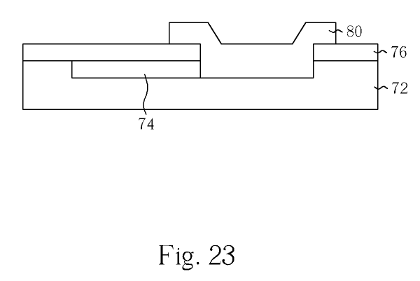

As shown in FIG. 22, a patterned mask, such as a patterned second dielectric layer 82 is disposed on the second metal layer 80. Next, as shown in FIG. 23, an etching process is performed by using the patterned second dielectric layer 82 as a mask to remove a portion of the second metal layer 80 and expose the first dielectric layer 76.

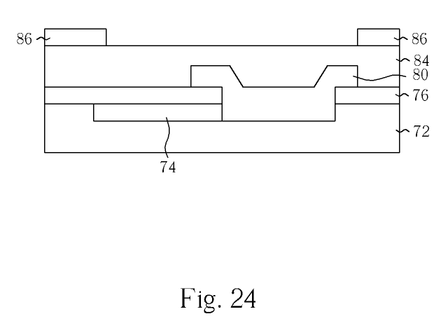

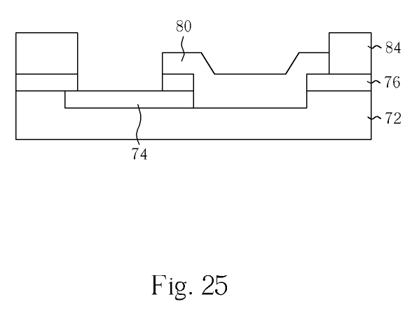

As shown in FIG. 24, a passivation layer 84 is disposed on the first dielectric layer 76 and the second metal layer 80, and another patterned mask, such as a patterned third dielectric layer 86 is disposed on the passivation layer 84 thereafter. Next, as shown in FIG. 25, an etching process is performed by using the patterned third dielectric layer 86 as a mask to remove a portion of the passivation layer 84 and the first dielectric layer 76 for exposing a portion of the first metal layer 74 and the second metal layer 80 and defining a probing region and an electrical connection region with respect to the exposed first metal layer 74 and the second metal layer 80.

As described in the previous embodiment, the location of the passivation layer 84 disposed on the first metal layer 74 and the second metal layer 80 can be adjusted accordingly. For instance, the passivation layer 84 can be disposed only on a portion of the first metal layer 74, only on a portion of the second metal layer 80, or on both the first metal layer 74 and the second metal layer 80.

Overall, in contrast to the conventional method for fabricating contact pads, the present invention uses two different metals to form a probing region and an electrical connection region of a contact pad. The probing region is used for providing a contacting surface for a test probe, whereas the electrical connection region is used for establishing an electrical connection in the later bumping or wire bonding process. By providing a contact pad having two different regions, the present invention is able to achieve probing process while prevent the surface of the contact pad from being damaged by the contact of the test probe.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a contact pad, comprising:
providing a substrate having at least one metal interconnects;
forming a first metal layer on the substrate for serving as a probing region; and
forming a second metal layer on the substrate for serving as an electrical connection region, wherein the first metal layer and the second metal layer are comprised of different material and are electrically connected.

2. The method for fabricating a contact pad of claim 1, wherein the substrate comprises a wafer or a silicon on insulator substrate.

3. The method for fabricating a contact pad of claim 1, wherein the first metal layer comprises aluminum or copper.

4. The method for fabricating a contact pad of claim 1, wherein the second metal layer comprises copper.

5. The method for fabricating a contact pad of claim 4 further comprising performing a bumping process for forming a bump on the second metal layer.

6. The method for fabricating a contact pad of claim 1, wherein the second metal layer comprises aluminum.

7. The method for fabricating a contact pad of claim 6 further comprising performing a wire bonding process for forming a wire on the second metal layer.

8. The method for fabricating a contact pad of claim 1 further comprising utilizing a test probe for performing a probing process on the first metal layer.

9. The method for fabricating a contact pad of claim 1 further comprising forming a patterned passivation layer on the first metal layer or the second metal layer for defining the probing region and the electrical connection region.

10. The method for fabricating a contact pad of claim 1 further comprising forming a patterned passivation layer on a portion of the first metal layer and the second metal layer for defining the probing region and the electrical connection region.

11. A contact pad, comprising:
a substrate having at least one metal interconnects;
a first metal layer disposed on the substrate for serving as a probing region; and
a second metal layer disposed on the substrate for serving as an electrical connection region, wherein the first metal layer and the second metal layer are comprised of different material and are electrically connected.

12. The contact pad of claim 11, wherein the substrate comprises a wafer or a silicon on insulator substrate.

13. The contact pad of claim 11, wherein the first metal layer comprises aluminum or copper.

14. The contact pad of claim 11, wherein the second metal layer comprises copper.

15. The contact pad of claim 14 further comprising a bump disposed on the second metal layer.

16. The contact pad of claim 11, wherein the second metal layer comprises aluminum.

17. The contact pad of claim 16 further comprising a wire disposed on the second metal layer.

18. The contact pad of claim 11 further comprising a patterned passivation layer disposed on the first metal layer or the second metal layer for defining the probing region and the electrical connection region.

19. The contact pad of claim 11 further comprising a patterned passivation layer disposed on a portion of the first metal layer and the second metal layer for defining the probing region and the electrical connection region.

20. A method for fabricating a contact pad, comprising:
providing a substrate having at least one metal interconnects and a first metal layer thereon;
forming a first dielectric layer on the substrate and the first metal layer;
forming an opening in the first dielectric layer for exposing a portion of the first metal layer;
forming a second metal layer on the first dielectric layer and in the opening for forming a metal plug electrically connecting the first metal layer and the second metal layer, wherein the first metal layer and the second metal layer comprise different materials;
removing a portion of the second metal layer;
forming a passivation layer on the second metal layer and a portion of the first dielectric layer; and
removing a portion of the passivation layer for exposing a portion of the first metal layer and the second metal layer, wherein the exposed portion of the first metal layer is a probing region and the exposed portion of the second metal layer is an electrical connection region.

21. The method for fabricating a contact pad of claim 20, wherein the substrate comprises a wafer or a silicon on insulator substrate.

22. The method for fabricating a contact pad of claim 20, wherein the first metal layer comprises aluminum or copper.

23. The method for fabricating a contact pad of claim 20, wherein the second metal layer comprises copper.

24. The method for fabricating a contact pad of claim 23 further comprising performing a bumping process for forming a bump on the second metal layer.

25. The method for fabricating a contact pad of claim 20, wherein the second metal layer comprises aluminum.

26. The method for fabricating a contact pad of claim 25 further comprising performing a wire bonding process for forming a wire on the second metal layer.

27. The method for fabricating a contact pad of claim 20 further comprising utilizing a test probe for performing a probing process on the first metal layer.

28. The method for fabricating a contact pad of claim 20 further comprising utilizing a patterned mask to remove a portion of the passivation layer and expos a portion of the first metal layer and the second metal layer for defining the probing region and the electrical connection region.

29. A contact pad, comprising:
a substrate having at least one metal interconnects;
a first metal layer disposed on the substrate, wherein the surface of the first metal layer is exposed for serving as a probing region;
a second metal layer disposed on the substrate for serving as an electrical connection region, wherein the first metal layer and the second metal layer comprise different materials; and
a metal plug, disposed between the first metal layer and the second metal layer for electrically connecting the first metal layer and the second metal layer.

30. The contact pad of claim 29, wherein the substrate comprises a wafer or a silicon on insulator substrate.

31. The contact pad of claim 29, wherein the first metal layer comprises aluminum or copper.

32. The contact pad of claim 29, wherein the second metal layer comprises copper.

33. The contact pad of claim 32 further comprising a bump disposed on the second metal layer.

34. The contact pad of claim 29, wherein the second metal layer comprises aluminum.

35. The contact pad of claim 34 further comprising a wire disposed on the second metal layer.

36. The contact pad of claim 29 further comprising a dielectric layer disposed between the first metal layer and the second metal layer, wherein the dielectric layer exposes a portion of the first metal layer.

37. The contact pad of claim 36 further comprising a patterned passivation layer disposed on the first metal layer or the second metal layer for defining the probing region and the electrical connection region.

38. The contact pad of claim 36 further comprising a patterned passivation layer disposed on a portion of the first metal layer and the second metal layer for defining the probing region and the electrical connection region.

39. The contact pad of claim 29, wherein the metal plug comprises same material as the second metal layer.
